(19) United States
(12) Patent Application Publication
(10) Pub. No.: US 2021/0278446 A1
(43) Pub. Date: Sep. 9, 2021

(54) MEASURING CIRCUIT FOR REGISTERING AND PROCESSING SIGNALS AND MEASURING DEVICE FOR USING SAID MEASURING CIRCUIT

(71) Applicant: Kistler Holding AG, Winterthur (CH)

(72) Inventor: Flavio Rosa, Baden (CH)

(21) Appl. No.: 17/260,784

(22) PCT Filed: Jul. 3, 2019
(86) PCT No.: PCT/EP2019/067823

§ 371 Date: Jan. 15, 2021

(30) Foreign Application Priority Data
Jul. 19, 2018 (EP) 18184555.3

(51) Int. Cl. G01R 19/25; G01R 19/00; G01L 5/167; G01D 3/032

(52) U.S. Cl. CPC G01R 19/2506; G01D 3/032; G01L 5/167; G01R 19/0053

(57) ABSTRACT

A measuring circuit for registering and processing signals received from a transducer having a plurality of transducer elements includes a first signal input, a second signal input and a third signal input. The first signal input is configured to receive a first signal from a first transducer element. The second signal input is configured to receive a first signal from a second transducer element. The third signal input is configured to receive a second signal sum indicative of a sum of a second signal from each of the plurality of transducer elements, each of the second signals being an inverse of a corresponding first signal. A processor is electrically coupled to the three signal inputs and is configured to register each of the first signals individually; register the second sum signal; and generate a differential signal based on the first and second signals.

### CROSS-REFERENCE TO RELATED APPLICATIONS

Not applicable.

### FIELD OF THE INVENTION

The present invention relates to a measuring circuit for registering and processing electrical signals from transducers as well as to a measuring device consisting of a measuring circuit and a transducer, and a cable that connects said measuring circuit and transducer.

### BACKGROUND OF THE INVENTION

Measuring circuits for registering signals and for processing differential signals are known in particular from metrology. Such a measuring circuit registers the signals of a transducer, for example. A transducer detects at least one physical variable which is the so-called input variable and outputs at least one physical variable which is the so-called output variable. An output variable is for example a voltage, a current or a charge. This output variable is transmitted to a measuring circuit via a cable for which purpose said cable comprises at least two conductors each of which conducts a signal. Of interest in this respect is usually the difference between the signals of the two conductors such as the difference in electric potential between two conductors in which case the difference is determined in the form of a voltage. However, electric, magnetic or electromagnetic fields may occur and interfere with these signals. Transducers are known which register one physical variable, such as the Kistler 1-component force sensor type 9001A described in data sheet 9001a_000-105d-05.18, and an example is shown in FIG. 1 of commonly owned U.S. Patent Application Publication No. 2016-0290879, which is hereby incorporated herein by this reference for all purposes. In addition, transducers are available which register a plurality of physical variables such as type 9047C from Kistler which registers three forces and is described in data sheet 9047C_000-592d-04.07. Commonly owned U.S. Pat. No. 3,566,163, which is hereby incorporated herein by this reference for all purposes, discloses the general layout of a 3-component force sensor of the Type 9047C. Furthermore, transducers are known which register other physical variables such as the multicomponent dynamometer type 9139AA from Kistler described in data sheet 9139AA_003-198d-06.15, and the dynamometer is described in commonly owned U.S. Pat. No. 5,821,432, which is hereby incorporated herein by this reference for all purposes.

A measuring circuit for detecting an interference is known from EP0987554B1, which has a counterpart in U.S. Pat. No. 6,498,501, which is hereby incorporated herein by this reference for all purposes. EP0987554B1 discloses a measuring circuit comprising a transducer connected to a measuring circuit by a transmission cable wherein said transducer is connected symmetrically and said measuring circuit calculates the sum of the signal values at the terminals of the transducer to provide an error signal, and calculates the difference between the signal values at the terminals of the transducer.

Furthermore, EP0987554B1 describes means for imposing an artificial interference in the form of an auxiliary signal that is fed to the terminals of the transducer to detect errors and interference effects at the transducer and/or other portions of the circuit.

However, an inherent disadvantage is that although the artificially generated interference is detected for diagnostic purposes, the registered differential signal may still be falsified by an interference from outside the system. In addition, the subject matter of EP0987554B1 is only applicable to transducers with only one transducer element that transmits a registered signal to a measuring circuit via two signal conductors of a cable.

### OBJECTS AND SUMMARY OF THE INVENTION

It is a first object of the present invention to reduce the costs of a measuring circuit for registering signals and for processing them into differential signals by reducing the number of signal inputs so that less than two signal inputs are present per transducer element of the transducer wherein the transducer comprises at least two transducer elements.

It is another object of the present invention to register the signals of the transducer elements and to minimize the impact of external interferences on the signals.

At least one of these objects is achieved by the features described below.

The invention relates to a measuring circuit for registering and processing signals; wherein a number of first signals and an equal number of second signals are provided, wherein the measuring circuit is adapted to generate at least one differential signal from a first signal and a second signal; wherein each first signal corresponds to one negated second signal; wherein the number of first signals is at least two; wherein the measuring circuit comprises a number of signal inputs that corresponds to the number of first signals; wherein the measuring circuit comprises a further signal input; wherein the first signals are registered individually by the measuring circuit and wherein the sum of the second signals, the so-called second signal sum, is registered.

Transducers generally detect at least one input variable by means of a transducer element arranged in the transducer that is sensitive for this input variable. The transducer element usually comprises two contacts each of which comprises a signal. This is known to those skilled in the art as symmetrical signal transmission. The determination of the output variable can be done by determining the two signals. Thus, in the case of electric voltage being the output variable this is determined by determining the difference in the electric potentials of the contacts. Methods for determining electric charge or electric current output variables are well known to those skilled in the art. Therefore, the output variable is also referred to as the differential signal.

Usually, the contacts are connected in an electrically conductive manner to a plug connector arranged at the transducer. A cable that comprises the respective counterpart of the connector transmits the signals to the measuring circuit. Alternatively, a cable associated with the transducer may also be connected directly to the contacts.

A transducer element is connected symmetrically when a reference value exists by which the two signals of the transducer element are negated with respect to one another. A variation of the input variable results in an inverse variation of the first signal and the second signal relative to each other. The reference value is independent of a change in the absolute values of the signals of the input variable. The reference value can be variable with time.

Often, the reference value is a reference potential. For clarity, the reference value will be assumed to be zero in the description that follows. Thus, the reference potential is equal to ground potential. However, it is also possible to use a reference value which is different from zero.

A transducer that is suitable for providing signals for the measuring circuit according to the invention comprises at least two transducer elements each having a first contact and a second contact with respective first and second signals. The second contacts of the transducer elements are always combined in such a way that their signals are added. This sum of the second signals is referred to as the second signal sum and is transmitted to a signal input of the measuring circuit. The signals corresponding to the first contacts are transmitted to separate signal inputs of the measuring circuit. This reduces the number of signal inputs as compared to a measurement circuit which registers all first and all second signals individually. Since each signal input requires separate signal detection within the measuring circuit, the costs for manufacturing the measuring circuit are reduced. Moreover, the measurement circuit is also more robust because the number of components required is reduced. In addition, the manufacture of the cable that transmits the signals to the measuring circuit is more cost-effective since fewer conductors are needed.

Providing a signal or a provided signal is understood to mean providing the provided signal for further use, for example for electronic processing. Providing a signal also includes the ability to store the signal in an electronic data memory and to load the signal from this data memory. Providing a signal also includes displaying the signal on a display. In the following, a provided signal usually is an analog signal. However, those skilled in the art may also put the following description into practice using digital signals.

The differential signal of the first and second signals of a transducer element can be calculated by the measuring circuit by means of an arithmetic element using the signals provided at the signal inputs said signals being the second signal sum and the individual first signals. An arithmetic element is adapted to relate a plurality of signals to each other by means of addition, subtraction, division or multiplication and to provide the result.

In addition to the differential signals of the transducer elements the measuring circuit is also adapted to calculate an interference signal. An interference signal is a change of the signals that is not due to a variation in the registered input variable but due to an interference. An interference is the occurrence of an electric or magnetic field or an electromagnetic field, for example. If a transducer or a cable is located in the spatial area in which an interference exists, an interference signal with substantially identical phase position will occur in electrically conductive components of the transducer such as the first and second contacts of a transducer element or in the conductors of the cable. This is known to those skilled in the art as common mode interference. Usually, the interference originates from an external source.

The magnitude of the interference signal corresponds to an input of the interference into a cable or into a transducer.

In the detection of the interference signal by the measuring circuit an adder first calculates the sum of the provided first signals to obtain the first signal sum. An adder is an element adapted to sum up two signals and to provide the sum. Afterwards, an adder calculates the sum of the first signal sum and the provided second signal sum which gives the interference signal. If no interference exists, the interference signal will be zero. An interference signal different from zero indicates that there is an interference which may be quantified by means of the detected interference signal.

If the reference potential is different from zero, the interference signal will be different from zero also in the absence of an interference. In the case of no interference the interference signal is equal to the interference potential multiplied by the number of registered signals. For reasons of clarity, the reference potential will be assumed to be zero and therefore equal to ground potential in the description that follows. However, in the practice of the present invention it is also possible to use a reference potential that is different from zero. Since the reference potential is known, the formulas mentioned below may be easily adapted accordingly.

The impact of the interference on the input signals of the measuring circuit is substantially the same so that the interference may essentially be eliminated from the provided first signals and the provided second signal sum by means of an arithmetic element.

The measuring circuit calculates the differential signals of the transducer elements by eliminating the detected interference to result in essentially interference-free differential signals.

An arrangement of a transducer, cable and measuring circuit is a measuring device.

### BRIEF DESCRIPTION OF THE DRAWINGS

In the following, the invention will be explained by way of example referring to the figures in which

FIG. 1 shows a schematic partial view of an embodiment of the measuring circuit for a number N of first signals,

FIG. 2 shows a schematic partial view of an embodiment of a measuring device comprising the measuring circuit of FIG. 1, a cable and a transducer,

FIG. 3 shows a schematic partial view of an embodiment of the measuring circuit for 2 first signals,

FIG. 4 shows a schematic partial view of an embodiment of the measuring circuit for 3 first signals,

FIG. 5 shows a schematic partial view of an embodiment of a measuring device comprising the measuring circuit of FIG. 1, a cable and a transducer,

FIG. 6 shows a schematic partial view of an embodiment of a measuring device comprising the measuring circuit of FIG. 1, a cable and a transducer,

FIG. 7 shows a schematic partial view of an embodiment of a measuring device comprising the measuring circuit of FIG. 1, a cable and a transducer,

FIG. 8 shows a schematic representation of an example with three first signals of the first signals and of the second signal sum both overlaid with an interference signal as provided at the signal inputs,

FIG. 9 shows a schematic representation of an example with three first signals of the first signals and of the second signal sum both overlaid with an interference signal, the first signal sum as well as the detected interference signal within the measuring circuit,

FIG. 10 shows a schematic representation of an example with three first signals of the first signals and of the second signal sum both overlaid with an interference signal, the first signal sum, the detected interference signal, a differential signal, and an interference-corrected differential signal.

### DETAILED DESCRIPTIONS OF EXEMPLARY EMBODIMENTS

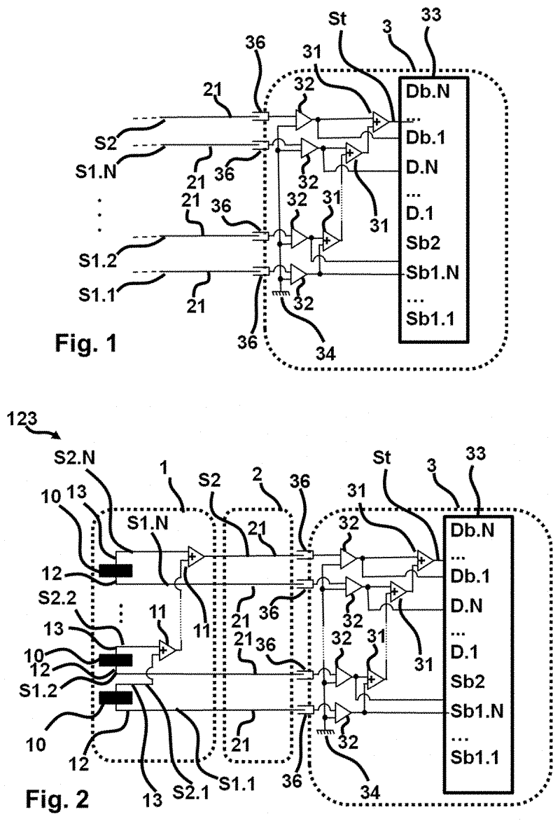

FIG. 1 shows a schematic partial view of the measuring circuit 3 comprising a number N of signal inputs 36 and an additional signal input 36. Signal inputs 36 are configured to register and provide a number N of first signals S1.1 to S1.N and to register and provide a sum S2 of second signals S2.1 to S2.N wherein the number N is a natural number greater than one.

$$S 2 = {\sum }_{n = 1}^{N} S 2 . n$$

Regarding the first signals S1.1 to S1.N and the second signals S2.1 to S2.N, a first signal S1.1 to S1.N corresponds to the negative value of a second signal S2.1 to S2.N for each value of the signal in the case of no interference:

S1.n=−S2.n∀n∈[1,N]

A variation of the first signal S1.1 to S1.N is accompanied by an equal but opposite variation of the second signal S2.1 to S2.N.

In the case considered, the reference potential at which a first signal and a second signal are negated with respect to one another is equal to zero. In the case of a reference potential different from zero the above and the following formulas must be adapted accordingly.

The first signals S1.1 to S1.N and the sum S2 of the second signals S2.1 to S2.N are each transmitted by a conductor 21 to a signal input 36 of the measuring circuit 3.

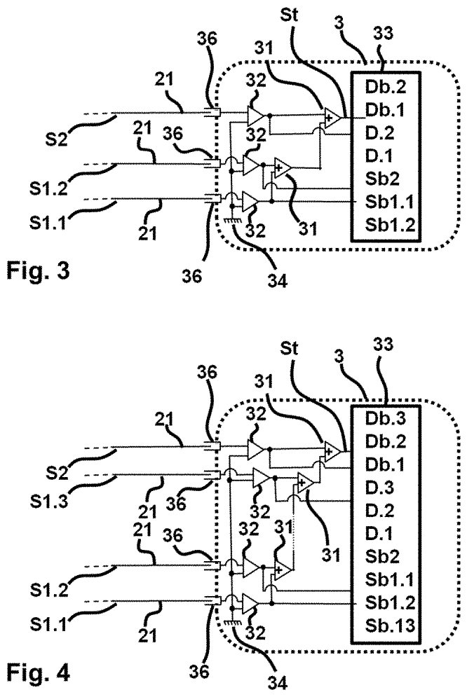

FIG. 3 exemplarily shows a measuring circuit comprising three signal inputs and which is therefore adapted to register two first signals S1.1 and S1.2 as well as the second signal sum S2.

FIG. 4 exemplarily shows a measuring circuit comprising four signal inputs and which is therefore adapted to register three first signals S1.1 to S1.3 as well as the second signal sum S2.

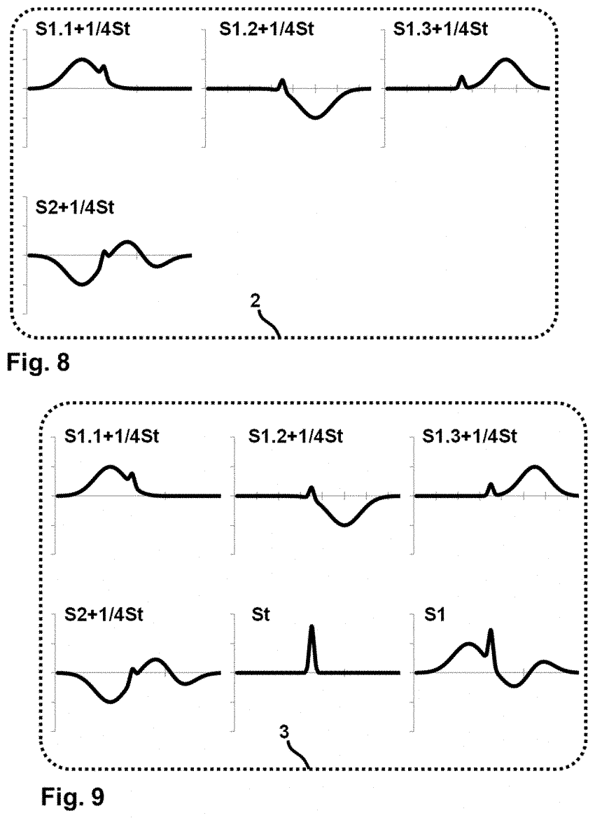

In the case of an interference this interference will affect each of the provided first signals S1.1 to S1.N and the provided second signal sum S2 to an equal amount, said interference being in phase. Therefore and as schematically shown in FIG. 8, at each signal input 36 of the measuring circuit 3 a proportion of an interference signal St caused by the interference will be additively overlaid on a first signal S1.1 to S2.N or the second signal sum S2, respectively. The proportion 1/(N+1) of the overlaid interference signal St is given by the number of signal inputs 36 of the measuring circuit 3.

The first signals S1.1 to S1.N with the overlaid proportional interference signal St/(N+1) are added up within the measuring circuit 3 and the result is provided as the first signal sum S1, as shown in FIG. 9.

$$S 1 = {\sum }_{n = 1}^{N} ( S 1 . n + \frac{St}{N + 1} )$$

The interference signal St may be determined by adding up the first signal sum S1 and the second signal sum S2 wherein the second signal sum S2 is additionally overlaid by the proportional interference signal St/(N+1). Therefore, the second signal sum S2 is given by the ideal interference-free second signal sum S2′ and the interference signal St/(N+1).

$$S 2 = S {2}^{′} + \frac{S t}{N + 1}$$

Thus, the interference signal St is determined by:

$$( S 1 ) + ( S 2 ) = ( {\sum }_{n = 1}^{N} ( S 1 . n + \frac{S t}{N + 1} ) ) + ( ( {\sum }_{n = 1}^{N} S 2 . n ) + \frac{S t}{N + 1} ) == ( N * \frac{S t}{N + 1} + {\sum }_{n = 1}^{N} ( S 1 . n ) ) + ( ( {\sum }_{n = 1}^{N} S 2 . n ) + \frac{S t}{N + 1} ) == N * \frac{S t}{N + 1} + \frac{S t}{N + 1} + {\sum }_{n = 1}^{N} ( S 1 . n + S 2 . n ) = N * \frac{S t}{N + 1} + \frac{S t}{N + 1} = S t$$

The total interference signal St may, thus, be determined from the first signals S1.1 to S1.N and the second signal sum S2 provided at the signal inputs 36 together with the respective overlaid proportional interference signal St/(N+1). The interference signal is exemplarily shown in FIG. 9.

When the interference signal is known, the respective proportion of the interference signal may simply be subtracted from the first signals S1.1 to S1.N and the second signal sum S2 provided at the signal inputs 36 in an arithmetic element. The resulting interference-corrected first signals Sb1.1 to Sb1.N and interference-corrected second signal sum Sb2 are shown in FIGS. 1 to 7.

Adding up the first signals S1.1 to S1.N to obtain a first signal sum S1 is done by means of an adder 31. The adder 31 is arranged in the measuring circuit 3. Similarly, adding up the first signal sum S1 and the second signal sum S2 is also done by means of an adder 31. Components which add two or more signals are known to persons skilled in the art in the field of electrical engineering. Thus, adding up digital signals is for example performed by means of microprocessors. The adding up of analog signals is performed in the simplest case, for example for charges or currents, by means of a conductive connection between two conductors.

A differential signal D.1 to D.N of a first signal S1.1 to S1.N and a second signal S2.1 to S2.N is calculated from the provided first signals S1.1 to S1.N and the second signal sum S2. For this purpose, all first signals except the first signal S1.k, k being in the range from 1 to N including the limits, for which the differential signal D.1 to D.N is to be calculated are added to the second signal sum S2. Moreover, overlaid on the first signals S1.1 to S1.N and the second signal sum S2, respectively, is still the proportional interference signal St/(N+1).

$$( S 2 ) + ( {\sum }_{n = 1 ⩓ n \neq k}^{N} ( S 1 . n + \frac{S t}{N + 1} ) ) == ( ( {\sum }_{n = 1}^{N} S 2 . n ) + \frac{S t}{N + 1} ) + ( ( N - 1 ) * \frac{S t}{N + 1} + ( {\sum }_{n = 1 ⩓ n \neq k}^{N} S 1 . n ) ) == \frac{S t}{N + 1} + ( N - 1 ) * \frac{S t}{N + 1} + ( {\sum }_{n = 1}^{N} S 2 . n ) + ( {\sum }_{n = 1 ⩓ n \neq k}^{N} S 1 . n ) == \frac{S t}{N + 1} + ( N - 1 ) * \frac{S t}{N + 1} + ( {\sum }_{n = 1}^{N} S 2 . n ) + ( {\sum }_{n = 1 ⩓ n \neq k}^{N} S 1 . n ) = N * \frac{S t}{N + 1} S 2 . k$$

After which the difference from the first signal S1.k, k1 from 1 to N, is calculated.

$$( N * \frac{S t}{N + 1} S 2 . k ) - ( S 1 . k + \frac{S t}{N + 1} ) = \frac{N - 1}{N + 1} * S t * ( S 2 . k - S1 . k ) = D . k$$

A known proportion (N−1)/(N+1) of the differential signal D.1 to D.N consists of the interference signal St. This proportion is known and the interference signal St has already been determined so that the differential signal D.1 to D.N may be corrected by eliminating the proportion of the interference St from the differential signal D.1 to D.N.

$$D . k - \frac{N - 1}{N + 1} S t = D b . k ,$$

k being in the range from 1 to N including the limits

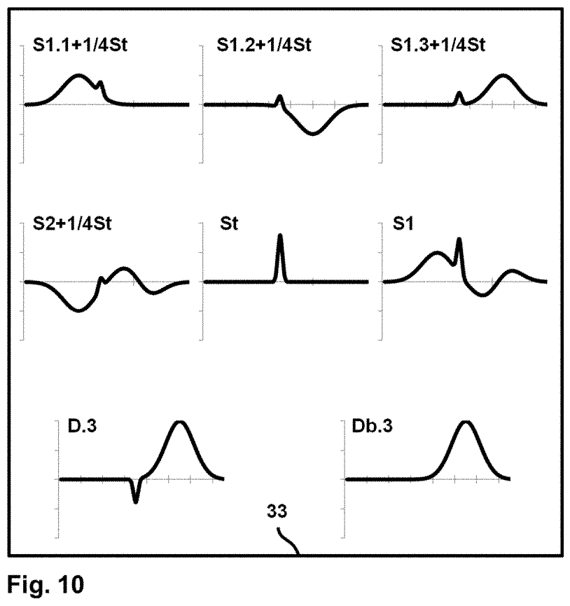

The interference-corrected differential signal Db.1 to Db.N is free from the interference signal St that affected the signals. Afterwards, interference-corrected differential signals Db.1 to Db.N may be determined for all first signals S1.1 to S1.N. The differential signal D.1 to D.N and the interference-corrected differential signal Db.1 to Db.N are exemplarily shown in FIG. 10.

In one embodiment, measuring circuit 3 includes analog-to-digital converters which digitize each first signal S1.1 to S1.N as well as the sum S2 of the second signals. The term first signal S1.1 to S1.N or second signal S2.1 to S2.N is independent of whether a signal exists in the measuring circuit 3 in analog or digital form. Operations within measuring circuit 3 may either be performed by digital signal processing or analog signal processing. Thus, the adder 31 adapted to add two signals is realized either by a microprocessor or by a suitable analog circuit. Likewise, the arithmetic element 33 which relates a plurality of signals to each other by means of addition, subtraction, division or multiplication is realized either by a microprocessor or by a suitable analog circuit.

In one embodiment, each signal input 36 is connected in an electrically conductive manner to a respective amplifier 32, said amplifier 32 being arranged within the measuring circuit 3 as shown in FIGS. 1 to 4. An amplifier 32 comprises at least two signal inputs of which a first one is connected in an electrically conductive manner to the signal input 36 of the measuring circuit 3. A second signal input of the amplifier 32 is connected to a reference potential 34. In one embodiment, the amplifier 32 may also include an analog-to-digital converter. An arrangement of the amplifier 32 in the proximity of a signal input 36 is advantageous for further signal processing within the measuring circuit 3 which for an amplified signal is less susceptible to interference.

In one embodiment, amplifier 32 converts the physical variable of a first signal S1.1 to S1.N and the second signal sum S2 into another physical variable. For a first signal S1.1 to S1.N and the second signal sum S2 that are a charge, for example, the amplifier thus preferably converts said charge into a voltage or current. This voltage or current is still called the first signal S1.1 to S1.N or second signal sum S2, respectively, regardless of the physical variable. The term first signal S1.1 to S1.N or second signal sum S2 is independent of the physical variable by which the first signal or the second signal sum is represented or into which physical variable the first signal S1.1 to S1.N or second signal sum S2 may be converted within the measuring circuit 3.

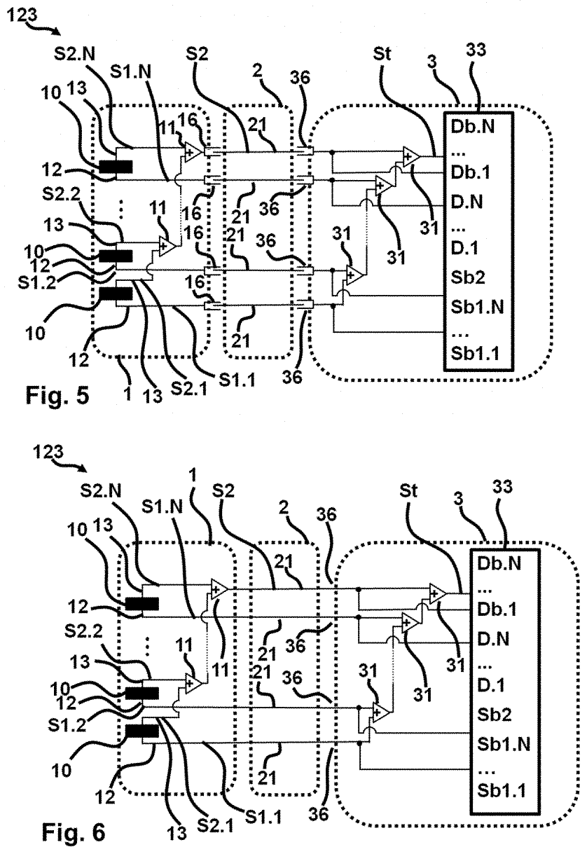

In one embodiment, no amplifier 32 is required in the measuring circuit 3 due to the nature of the first signals S1.1 to S1.N and the second signal sum S2, as shown in FIGS. 5 to 7.

Advantageously, measuring circuit 3 is used together with a suitable transducer 1 as well as a cable 2 that connects the transducer 1 and measuring circuit 3. Such an arrangement of transducer 1, cable 2 and measuring circuit 3 is referred to as a measuring device 123. A measuring device 123 is exemplarily shown in FIG. 2.

A transducer 1 registers at least one physical variable. For this purpose, at least one transducer element 10 is arranged in transducer 1 which registers the physical variable and carries a first contact 12 and a second contact 13. Transducer element 10 provides a first signal S1. to S1.N at the first contact 12 and a second signal S2.1 to S2.N at the second contact 13. A signal is for example a voltage or a current or a charge. A physical variable is, for example, a force, a pressure, an acceleration, a torque, a voltage, a current, a charge, a temperature, a magnetic flux density, photometric variables or any other physical variable.

In one embodiment, the transducer 1 is a multi-axis piezoelectric force transducer or a multi-axis piezoelectric acceleration transducer.

According to the invention, the second signals S2.1 to S2. N of the transducer elements 10 are added up by means of adders 11 to obtain a second sum S2. The structure of an adder 11 is dependent on the physical variable of the second signals S2.1 to S2.N. Thus, an adder 11 for a current or a charge may be an electrically conductive connection. However, more complex circuits that enable the addition of the second signals S2.1 to S2.N are also conceivable.

In one embodiment, the adders 11 are disposed within a transducer 1 as shown in FIGS. 2, 5 and 6. This has the advantage that a cable 2 connecting said transducer 1 to the measuring circuit 3 in an electrically conductive manner requires less conductors than in a case where all first and second signals are transmitted separately through the cable.

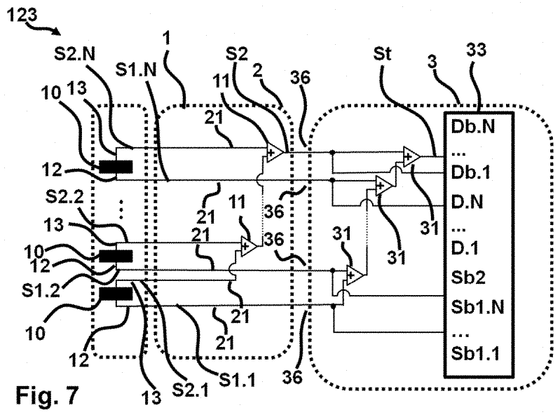

In one embodiment, the adders 11 are arranged within the plug of the cable 2 on the side of the transducer, as shown in FIG. 7. The plug of the cable 2 on the side of the transducer is the plug which connects the cable 2 to the transducer 1. This has the advantage that also transducers 1 that do not meet the requirements of combining the second signals may be used in a measuring device 123 with the measuring circuit 3. The adders 11 must be located close to the transducer, in particular in the plug on the side of the transducer, so that in the case of an interference an equal proportion of this interference will impact the provided first signals S1.1 to S1.N and the provided second signal sum S2, respectively, wherein said interference is in phase. When the connection between the cable 2 and the transducer 1 is made without a plug, then the adders 11 are to be incorporated into the cable 2 in very close proximity to the transducer 1 to ensure that an equal proportion of the interference impacts the provided first signals S1.1 to S1.N and the provided second signal sum S2, respectively, wherein said interference is in phase. In close proximity refers to a distance of less than 10% of the total length of the cable 2 between the transducer 1 and the measuring circuit 3.

In one embodiment, the adders 11 comprise an amplifier or an analog-to-digital converter, or both.

In one embodiment, conductors 21 of the cable 2 and contacts 12, 13 of the transducer 1 are connected in an electrically conductive manner by plug contacts 16, as shown in FIG. 5.

A plug contact consists of a plug and a socket of which one is present on the cable 2 and the respective other on the transducer and it serves to connect a conductor 21 of the cable 2 and a contact of the transducer 1 to one another in an electrically conductive manner.

In one embodiment, the cable 2 is non-detachably connected to the transducer 1, and the first contacts 12 and second contacts 13 are connected to the conductors 21 of the cable 2 by a material bond or a force-locked connection, as shown in FIGS. 2 and 6.

In one embodiment, the signal inputs 36 of the measuring circuit 3 are designed as plug contacts which connect the conductors 21 of the cable 2 to the measuring circuit 3 in an electrically conductive manner, as shown in FIGS. 1 to 5.

In one embodiment, the signal inputs 36 of the measuring circuit 3 are designed in a way that the cable 2 is non-detachably connected to the measuring circuit 3 and the conductors 21 of the cable 2 are connected to the signal inputs 36 of the measuring circuit 3 via a material bond or a force-locked connection, as shown in FIGS. 6 and 7.

In one embodiment (not shown) a plurality of transducers 1 are connected to the measuring circuit 3 in a way that the second signals S2.1 to S2.N of the transducer elements 10 located in different transducers 1 are combined in an additive manner. This may for example be an arrangement of a plurality of pressure transducers in a fluid system. These pressure transducers may be connectable to a cable 2 by a common plug contact, for example, and the second signals S2.1 to S2.N may be combined in the cable 2 in an additive manner. These pressure transducers may be piezoelectric or piezoresistive pressure transducers or ionization vacuum gauges or thermal conductivity vacuum gauges. Other applications in which transducer elements 10 are arranged in different transducers 1 are also conceivable.

An embodiment is also possible which combines various features of the embodiments disclosed in this document, provided this is feasible.

### LIST OF REFERENCE NUMERALS

1 transducer
2 cable
3 measuring circuit
10 transducer element
11 adder
12 first contact
13 second contact
16 signal output
21 conductor
31 adder
32 amplifier
33 arithmetic element
34 reference potential
36 signal input
123 measuring device
St interference signal
N number of transducer elements
S1.1 to S1.N first signal of a transducer element
S2.1 to S2.N second signal of a transducer element
S1 first signal sum
S2 second signal sum
S2′ interference-free second signal sum
Sb2 interference-corrected second signal sum
Sb1.1 to Sb1.N interference-corrected first signal
D.1 to D.N differential signal of a transducer element
Db.1 to Db.N interference-corrected differential signal of a transducer element

1-15. (canceled)

16. A measuring circuit for registering and processing signals received from a transducer having a plurality of transducer elements, the measuring circuit comprising:
at least a first signal input, a second signal input and a third signal input, the first signal input configured to receive a first signal from a first transducer element of the plurality of transducer elements, the second signal input configured to receive a first signal from a second transducer element of the plurality of transducer elements, the third signal input configured to receive a second signal sum indicative of a sum of a second signal from each of the plurality of transducer elements, each of the second signals being an inverse of a corresponding first signal; and
a processor electrically coupled to the first signal input, the second signal input and the third signal input, the processor configured to:
register each of the first signals individually;
register the second sum signal; and
generate at least one differential signal based, at least in part, on one of the first signals and one of the second signals.

17. The measuring circuit of claim 16, wherein the processor is further configured to:
add the first signals together to obtain a first signal sum;
add the first signal sum and the second signal sum to obtain an interference signal.

18. The measuring circuit of claim 17, wherein the processor is further configured to:
subtract a portion of the interference signal from each of the first signals to obtain a plurality of interference-corrected first signals; and
subtract the portion of the interference signal from the second signal sum to obtain an interference-corrected second signal sum.

19. The measuring circuit of claim 18, wherein the processor is further configured to:
generate a proportional interference signal based, at least in part, on a total number of signal inputs of the measuring circuit; and
subtract the proportional interference signal from the at least one differential signal to obtain at least one interference-corrected differential signal.

20. The measuring circuit of claim 16, further comprising:
a fourth signal input, the fourth signal input configured to receive a first signal from a third transducer element of the plurality of transducer elements.

21. The measuring circuit of claim 20, wherein the processor is configured to:
generate a first differential signal based, at least in part, on the second signal sum and the first signal received from the first transducer element;
generate a second differential signal based, at least in part, on the second signal sum and the first signal received from the second transducer element;
generate a third differential signal based, at least in part, on the second signal sum and the first signal received from the third transducer element of the plurality of transducer elements; and
determine an interference signal based, at least in part, on the second signal sum, the first signal received from the first transducer, the first signal received from the second transducer, and the first signal received from the third transducer.

22. The measuring circuit of claim 21, wherein the processor is further configured to:
generate a proportional interference signal based, at least in part, on a total number of signal inputs of the measuring circuit;
subtract the proportional interference signal from each of the first differential signal, the second differential signal and the third differential signal to obtain an interference-corrected first differential signal, an interference-corrected second differential signal, and an interference-corrected third differential signal.

23. A measuring device comprising:
a transducer comprising a plurality of transducer elements, each of the transducer elements comprising a first contact and a second contact, the first contact configured to output a first signal, the second contact configured to output a second signal, the second signal being an inverse of the first signal;
an adder, the adder configured to add the second signals together to obtain a second signal sum; and
a measuring circuit electrically coupled to the transducer via a cable, the measuring circuit comprising:
at least a first signal input, a second signal input and a third signal input, the first signal input configured to receive the first signal from a first transducer element of the plurality of transducer elements, the second signal input configured to receive the first signal from a second transducer element of the plurality of transducer elements, the third signal input configured to receive the second signal sum; and
a processor electrically coupled to the first signal input, the second signal input and the third signal input, the processor configured to:
register each of the first signals individually;
register the second sum signal;
generate at least one differential signal based, at least in part, on one of the first signals and one of the second signals;
add the first signals together to obtain a first signal sum;
add the first signal sum and the second signal sum to obtain an interference signal.

24. The measuring device of claim 23, wherein the adder is positioned inside the transducer.

25. The measuring device of claim 23, wherein the adder is positioned within a plug of the cable.

26. The measuring device of claim 23, wherein a magnitude of the interference signal corresponds to an input of an interference into the cable or the transducer.

27. The measuring device of claim 23, wherein each of the first signals and each of the second signals is indicative of a current, a voltage, or a charge.

28. The measuring device of claim 23, wherein the transducer is configured to detect at least one of an acceleration, a force, or a pressure.

29. The measuring device of claim 28, wherein at least one of the transducer elements is a piezoelectric transducer element.

30. A method for detecting at least two measured variable in an interference-free manner, the method comprising:
obtaining, by a measuring circuit, a first signal output by each of a plurality of transducer elements of a transducer electrically coupled to the measuring circuit;
obtaining, by the measuring circuit, a second signal sum from the transducer, the second signal sum indicative of a sum of a second signal output by each of the plurality of transducer elements, the second signal being an inverse of the first signal;
adding, by the measuring circuit, each of the first signals together to obtain a first signal sum;
determining, by the measuring circuit, an interference signal based, at least in part, on the first signal sum and the second signal sum, the interference signal indicative of an external electromagnetic interference of the first signals and the second signals or the second signal sum.

31. The method of claim 30, further comprising:
subtracting, via the measuring circuit, a portion of the interference signal from each of the first signals to obtain a plurality of interference-corrected first signals; and
subtracting, via the measuring circuit, the portion of the interference signal from the second signal sum to obtain an interference-corrected second signal sum.

32. The method of claim 31, further comprising:
calculating, via the measuring circuit, at least one differential signal based, at least in part, on the second signal sum and the first signals, the at least one differential signal corresponding to a difference between the first signal output by a first transducer element and the second signal output by the first transducer element; and
subtracting, via the measuring circuit, at least a portion of the interference signal from the at least one differential signal such that an existing interference signal is eliminated from the at least one differential signal.
